(19) United States
(12) Patent Application Publication
(10) Pub. No.: US 2025/0355816 A1
(43) Pub. Date: Nov. 20, 2025

(54) LEISURE RHYTHM FOR DATA BURST

(71) Applicant: Micron Technology, Inc., Boise, ID (US)

(72) Inventors: Jianying Zhu, Shanghai (CN); Bo Zhou, Shanghai (CN); Xuan Liu, Shanghai (CN)

(21) Appl. No.: 19/195,544

(22) Filed: Apr. 30, 2025

Related U.S. Application Data
(60) Provisional application No. 63/648,566, filed on May 16, 2024.

(51) Int. Cl. G06F 13/16

(52) U.S. Cl. CPC G06F 13/16; G06F 2213/16

(57) ABSTRACT

Methods, systems, and devices for leisure rhythm for data burst are described. A leisure rhythm may be implemented for data strobe signals. For example, a controller may drive a data strobe signal according to a first rate, or leisure rhythm, during one or more warm-up cycles of a warm-up period. After the warm-up period ends, a second data strobe rate may be used to transfer data for a read operation or a write operation using a data channel. In some examples, data strobe signals may include differential signals or single ended signals. Rates for data strobe signals may also ramp up using multiple rates over time.

### CROSS REFERENCE

The present application for patent claims priority to U.S. Patent Application No. 63/648,566 by Zhu et al., entitled “LEISURE RHYTHM FOR DATA BURST,” filed May 16, 2024, which is assigned to the assignee hereof, and which is expressly incorporated by reference in its entirety herein.

### TECHNICAL FIELD

The following relates to one or more of host systems or memory systems, including leisure rhythm for data burst associated with one or more of the host systems or the memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports leisure rhythm for data burst in accordance with examples as disclosed herein.

FIGS. 2A and 2B show examples of a signal diagram and a differential signal diagram that support leisure rhythm for data burst in accordance with examples as disclosed herein.

FIGS. 3A and 3B show examples of a signal diagram and a stair rhythm diagram that support leisure rhythm for data burst in accordance with examples as disclosed herein.

FIG. 4 shows a block diagram of a memory system that supports leisure rhythm for data burst in accordance with examples as disclosed herein.

FIGS. 5 and 6 show flowcharts illustrating a method or methods that support leisure rhythm for data burst in accordance with examples as disclosed herein.

### DETAILED DESCRIPTION

A memory system, in some cases, may coordinate (e.g., manage, handle, facilitate) signaling of data between a memory controller and one or more memory devices. The memory system may provide for a data (e.g., DQ) channel for connecting a memory system controller or a local memory controller with a memory device, for example, via a binary unit system (BUS). A host system, in some other cases, may coordinate (e.g., manage, handle, facilitate) signaling of data between a host system controller and the memory system. For example, one or more memory devices of the memory system may be directly coupled with the host system, or signals may be relayed between the host system and the one or more memory devices by one or more controllers (e.g., a host system controller, a memory system controller, or one or more local memory controllers).

A transfer of data associated with a memory system may involve a DQ BUS signal occurring at each rising and falling edge of a data strobe (e.g., DQs) signal at a fixed (e.g., set) rate (e.g., frequency). In some cases, continuous packets of data, or data bursts, may encounter poor quality during an initial transfer of data, where one or more miswrites or misreads may be caused by the DQ BUS or DQs signals failing to ramp up to full operation in time (e.g., due to a transition to direct current (DC) from alternating current (AC)). This effect may worsen as data transfer speed increases. A warm-up period including one or more warm-up cycles (e.g., warm-up period, warm-up cycle range) may, in some cases, address missed data by allowing a DQ BUS signal to ramp up before actual data is transferred, permitting data to be read or written afterwards. However, the warm-up period may be insufficiently long for a differential strobe signal (e.g., DQs signal for writes or a read enable (RE) signal on which DQs depends for reads) to overlap, or for a single ended strobe signal to be ready for a read or write operation, resulting in continued loss of data.

As described herein, missing data at the beginning of a data burst for read or write operations may be mitigated by implementing a slower rate (e.g., frequency, rhythm) for data strobe signals. For example, a leisure rhythm (e.g., a slower rate, such as a DQs rate), may be implemented during one or more warm-up cycles of a warm-up period for transferring data using a DQ BUS signal. After the warm-up period ends, a regular DQs rate, or regular rhythm, may be used to transfer actual data (e.g., bits, bytes) for a read or write operation. By reducing a quantity of data transferred during the warm-up period, more time may be allocated to allow a data strobe signal to be ready, so that the intended bits for a read or write are correctly transferred. For example, the slower rate may delay intended data bits to be read after an offset following the warm-up period once complementary differential signals of a differential strobe signal completely overlap. Using a slower rate may also allow a memory device to correctly read or write one or more first bits of a data burst at faster interface speeds, or data transfer rates, including faster open not-and (NAND) flash interface (ONFI) speeds. Data strobe rates may, in some cases, ramp up using multiple steps. Further, a data BUS signal may not match a slower strobe rate, and may instead be delayed to reduce a quantity of data for transfer during the warm-up period.

In addition to applicability in memory systems as described herein, techniques for implementing leisure rhythms for data bursts may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds (e.g., ONFI speeds) and reducing a quantity of missed data in data bursts, which may decrease processing or latency times, improve response times, improve a signal quality by reducing missed data, or otherwise improve user experience, among other benefits.

Features of the disclosure are illustrated and described in the context of systems, devices, and circuits. Features of the disclosure are further illustrated and described in the context of signal configurations, differential signal diagrams, stair rhythm diagrams, block diagrams, and flowcharts.

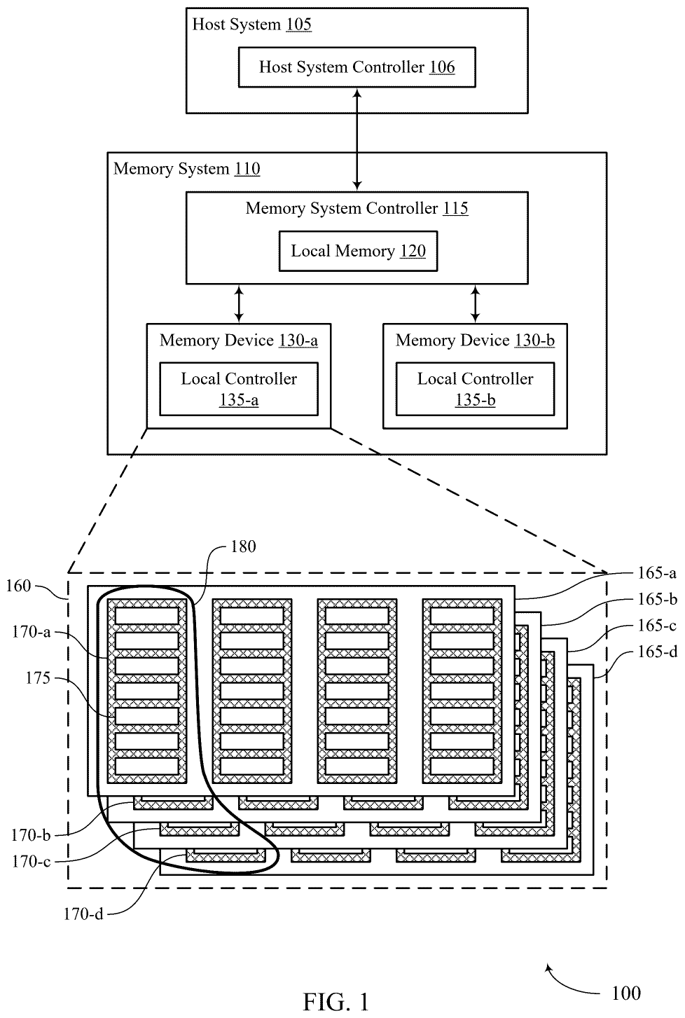

FIG. 1 shows an example of a system 100 that supports leisure rhythm for data burst in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some examples, the memory system 110 may facilitate the signaling of data between a controller (e.g., a memory system controller 115, one or more local controllers 135) and one or more memory devices 130. The memory system 110 might support a DQ channel for connecting one or more of a memory system controller 115, a local controller 135, or a host system controller 106, with the one or more memory devices 130. In some cases, such connections may be made possible using one or more BUSs, including a DQ BUS. One or more of the memory system controller 115, the local controller 135, or the host system controller 106 may transfer data using a DQ BUS signal at each rising and falling edge of a DQs signal at a set rate (e.g., frequency). In some cases, data bursts may experience poor quality (e.g., less than or equal to a threshold) during an initial data transfer, where one or more bits may be missed at one or more controllers (e.g., one or more of a host system controller 106, a memory system controller 115, or a local controller 135) of the host system 105 or the memory system 110 due to the DQ BUS or DQs signals failing to ramp up before data transfer begins. This may further degrade as data transfer speed increases. In some examples, the host system 105 and the memory system 110 may implement one or more warm-up cycles to allow a DQ BUS signal to ramp up before actual data transfer, and may permit data for reading or writing after a warm-up period. However, a warm-up period may be insufficient for a differential DQs signal to overlap for one or more first bits of a read or write operation, or for a single ended DQs signal to be ready for a read or write operation, resulting in continued loss of data.

As described herein, the memory system 110 and the host system 105 may mitigate missed data at the beginning of a data burst by implementing a slower rate (e.g., rate, frequency, rhythm) for data strobe signals. For example, for a write operation, the host system 105 may implement (e.g., via the host system controller 106) a slower DQs rate (e.g., leisure rhythm, or leisure rate) during one or more warm-up cycles of a warm-up period. During a read operation, the memory system 110 may implement (e.g., via the memory system controller 115 or one or more local controllers 135) the slower DQs rate based on (e.g., in response to) the host system 105 implementing a read strobe signal, such as an RE signal, at the slower rate. After the warm-up period ends, a regular DQs rate (e.g., regular rhythm) may be used to transfer actual data (e.g., bits, bytes) for a read operation or write operation. By reducing a quantity of data transferred during the warm-up period, more time may be allocated to allow complementary differential signals of a differential DQs signal to cross, or for a single ended DQs signal to be ready, so that intended bytes for the read or write operation are correctly transferred. Using a slower DQs rate may also allow a memory device 130 or the memory system 110 (e.g., NAND device, NAND system, among other memory devices and memory systems) to utilize faster interface speeds, or data transfer rates, with less missed data, such as ONFI speeds.

The system 100 may include any quantity of non-transitory computer readable media that support leisure rhythm for data burst. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

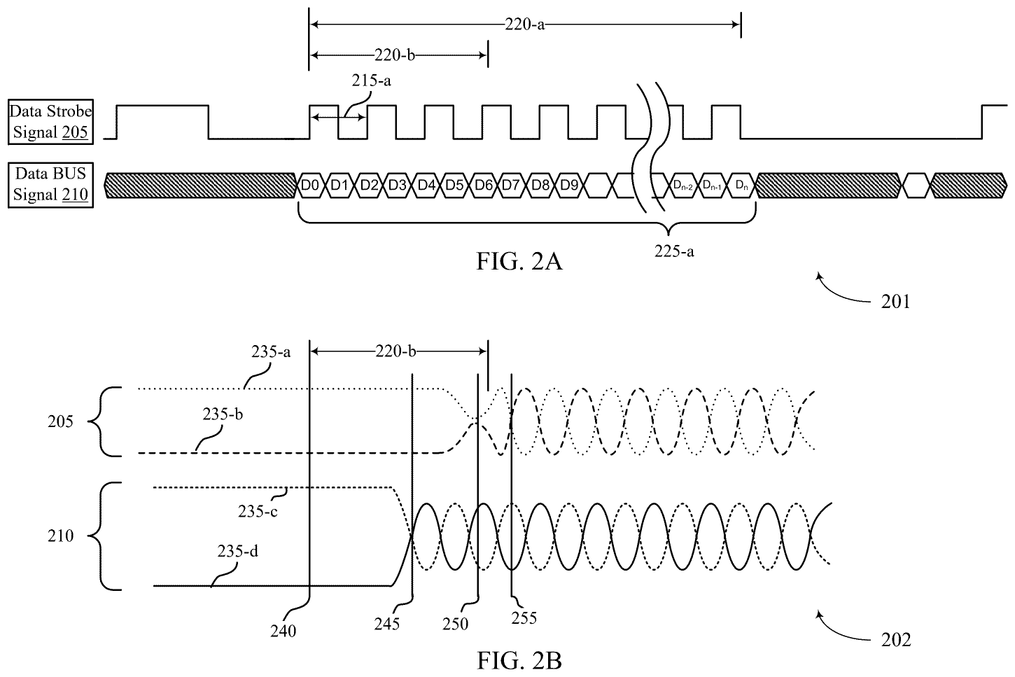

FIG. 2A shows an example of a signal diagram 201 that supports leisure rhythm for data burst in accordance with examples as disclosed herein, and FIG. 2B shows an example of a differential signal diagram 202 that supports leisure rhythm for data burst in accordance with examples as disclosed herein. One or more aspects of the signal diagram 201 and the differential signal diagram 202 may be implemented by one or more aspects of the system 100. For example, the signal diagram 201 may include a data strobe signal 205 and a data BUS signal 210 (e.g., for a data channel), which may be communicated (e.g., output) between one or more of a memory system controller 115 or a host system controller 106 and a memory device 130, as described with reference to FIG. 1. The data strobe signal 205 may be driven or communicated (e.g., output) using a set rate (e.g., frequency, rhythm). For example, the data strobe signal 205 may be communicated using a periodicity 215-a corresponding to a fixed rate for a duration 220-a of an operation (e.g., a transfer operation, a write operation, a read operation). For example, the duration 220-a may represent a data burst of a data transfer operation, such as an ONFI burst.

The signaling in FIGS. 2A and 2B may be associated with either a read operation or a write operation for a memory device 130. For example, during a write operation, a host system 105 (e.g., an ASIC) may transfer data (e.g., data-in) to a memory device 130 (e.g., a NAND device) by using a host system controller 106 to drive, or toggle, the data strobe signal 205 according to the fixed rate (similar to a clock signal) from a beginning cycle to an ending cycle of the duration 220-a. A cycle may represent a single period of a periodicity 215 including a rising and falling edge. Additionally, or alternatively, during a read operation, a controller of a memory system 110, such as a memory system controller 115 or a local controller 135, may drive the data strobe signal 205 to transfer data from a memory device 130 to one or more of the memory system controller 115 or the local controller 135 to the host system controller 106. In some examples, the data strobe signal 205 may be driven during a read operation to match a rate of an RE signal driven by the host system controller 106 of the host system 105 and received at the memory device 130.

To obtain data, a receiving device (e.g., a host system 105, a memory system 110) may latch data transmitted via the data BUS signal 210 using the data strobe signal 205. For example, bytes D0, D1, D2, D3, D4, D5, D6, D7, D8, D9, through Dₙ₋₂, Dₙ₋₁, and Dₙ may represent bytes of a data burst 225-a, where the data BUS signal 210 may be an example of an 8 bit DQ [0:7] BUS signal. During a read operation or a write operation, a receiving device (e.g., a host system 105, a memory system 110) may receive and store each of the bytes D0-Dₙ of the data burst 225-a at a respective rising or falling edge of the data strobe signal 205 driven by a transmitting device (e.g., a host system 105, a memory system 110). In some examples, one or more early byte cycles at the beginning of the data burst 225-a may be associated with bad signal quality, resulting in one or more bytes being missed or incorrectly latched. For example, this may be due to ramp up of one or more of the data strobe signals 205 or data BUS signal 210, or both. In some examples, slow ramp up for a signal may be due to physical limitations of different components or material of a driving device limiting a transition time from a DC to an AC current.

In some cases, the signal diagram 201 may include one or more warm-up cycles of a duration 220-b (e.g., warm-up duration, warm-up period) to mitigate poor signal quality. For example, with respect to FIG. 2B, the differential signal diagram 202 may illustrate an example where the data strobe signal 205 and the data BUS signal 210 may each include a respective pair of complementary differential signals. In some cases, the data strobe signal 205 may be a differential DQs signal including differential signals 235-a and 235-b while the data BUS signal 210 may be a differential DQ BUS signal including differential signals 235-c and 235-d in relation to the data burst 225-a. After the start of a read or write operation at 240, the data strobe signal 205 and the data BUS signal 210 may include a time period before respective differential signals 235 cross to enable transmission of data and storage. For example, the differential signals 235-c and 235-d of the data strobe signal 205 may cross at 245, resulting in a misread or miswrite of the bytes D0, D1, D2, and D3.

In some cases, a transmitting device (e.g., a host system 105, a memory system 110) may refrain from transmitting data during a warm-up period such as the duration 220-b. For example, the bytes D0-D5 may be placeholder bytes (e.g., dummy bytes, padding bytes, null bytes) and may not represent actual information for transmission during the data burst 225-a. At 245, the differential signals 235-c and 235-c of the data BUS signal 210 may overlap before an end of the duration 220-b, which may allow the data BUS signal 210 to transmit, following the duration 220-b, data corresponding to bytes D6 and after. In contrast, the differential signals 235-a and 235-b of the data strobe signal 205 may have insufficient time to overlap before an end of the duration 220-b. For example, the differential signals 235-a and 235-b may fail to overlap at 250 (e.g., and a differential signal of an RE signal may also fail to overlap at a same or different time) and may not overlap until a next byte D7 at 255 (or until a later byte), resulting in a miswrite or misread of the data of the byte D6. Missing a single read or write event, such as the read or write of D6, may also cause a timeout at a host system (e.g., a host system 105). Additionally, or alternatively, for higher host interface speeds and data transfer speeds (e.g., ONFI speeds), a duty cycle may be shortened for the data BUS signal 210, resulting in more bytes in early cycles of a data burst that may also be missed, which may limit systems to a lower margin for data transfer speeds and for errors. Margin for transfer speed and error on one or more first bytes may be further worsened by a system utilizing a smaller strength (e.g., power, current, voltage) for driving a DC or AC signal such as the data strobe signal 205, which may delay overlap even further.

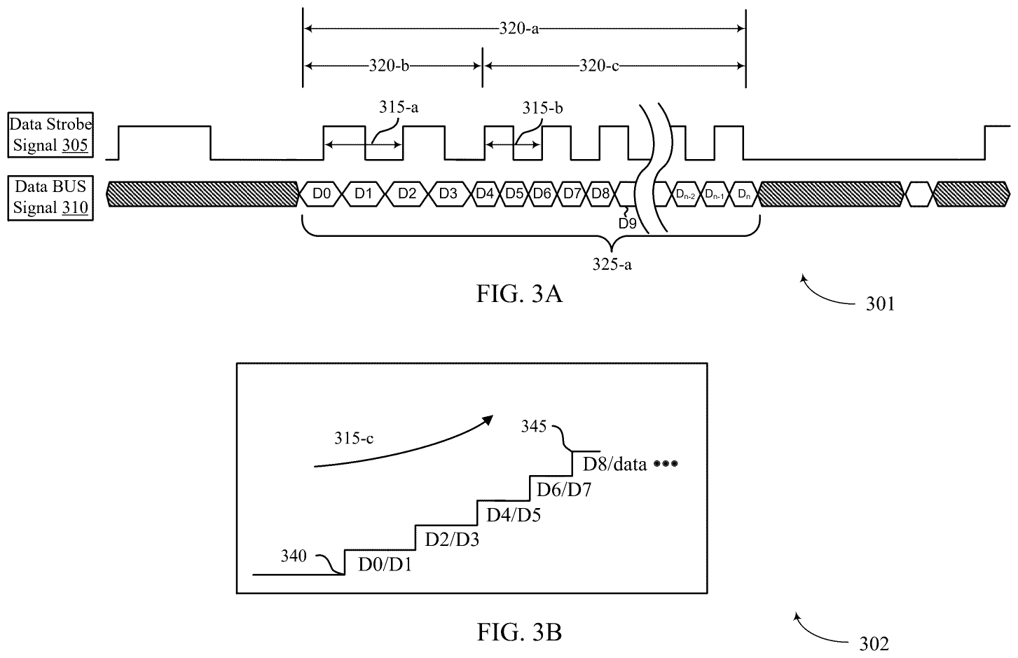

As described herein, techniques may be implemented to enable the data strobe signal 205 to mitigate one or more missed bytes at the beginning of a data burst by implementing a slower rate as illustrated with respect to FIGS. 3A and 3B. For example, by implementing a slower rate for the data strobe signal 205 at the beginning of the data burst 225-a (e.g., during the warm-up period), the data transfer for the data burst 225-a may be delayed to allow the strobe signal time to ramp up to mitigate one or more first bytes being missed by an RE signal or DQs signal and to gain a larger margin for ONFI speed.

FIG. 3A shows an example of a signal diagram 301 that supports leisure rhythm for data burst in accordance with examples as disclosed herein, and FIG. 3B shows a stair rhythm diagram 302 that supports leisure rhythm for data burst in accordance with examples as disclosed herein. One or more aspects of the signal diagram 301 and the stair rhythm diagram 302 may be implemented by one or more aspects of the system 100, the signal diagram 201, and the differential signal diagram 202. For example, the signal diagram 301 may include a data strobe signal 305 (e.g., DQs signal) and a data BUS signal 310 (e.g., a DQ BUS signal for a DQ channel), which may be communicated between one or more of a memory system controller 115 or a host system controller 106 and a memory device 130 (e.g., of a UFS, SSD, NAND (e.g., RawNAND), mNAND, or other type of memory with a host device). The data burst may be part of a data transfer operation performed during a duration 320-a for a data burst 325-a, such as an ONFI burst. In some cases, FIGS. 3A and 3B may illustrate implementation of a leisure rhythm for the data burst 325-a during a duration 320-b and a duration 320-c of a data transfer operation.

The signal diagram 301 may be associated with operations applicable to a write operation or a read operation for bytes D0-D9 through Dₙ similar to FIG. 2A. For a write operation, a controller (e.g., a host system controller 106, a memory system controller 115, a local controller 135) may drive the data strobe signal 305 according to a leisure rhythm during the duration 320-b (e.g., a first duration), where the leisure rhythm may be an example of a first rate corresponding to a periodicity 315-a. In some cases, the duration 320-a may be a warm-up range or warm-up period and may include one or more warm-up cycles. In some cases, data-in may be driven for a first several bytes of the data strobe signal 205 and the data BUS signal 210, such as the bytes D0-D3. The rate may be less than a second rate, or rhythm, for data transfer, which may have a periodicity 315-b that may be shorter than the periodicity 315-a. The data strobe signal 305 may also be driven according to the second rate during the duration 320-c (e.g., second duration) of the write operation, and may transfer data of the data burst 325-a via a data channel using the data BUS signal 310. Thus, the data transfer may be based on, or in response to, driving the data strobe signal 305 according to the first rate during the first duration and according to the second rate during the second duration.

In some cases, data transfer may refer to transmission of data from a transmitting device to a receiving device. For example, the write operation may involve writing the data of the data burst 325-a to one or more memory cells of a memory device 130 based on (e.g., in response to, after) sending, or transmitting, the data from a controller (e.g., one or more of a host system controller 106, a memory system controller 115, or a local controller 135) to the memory device 130. In some cases, to transfer the data for the write operation, a host system controller 106 may send the data directly to a local controller 135 of (or directly to) a memory device 130 (e.g., a receiving device), which may perform a write using the data. The host system controller 106 may also send the data to a memory system controller 115, which may forward the data to the local controller 135. Additionally, or alternatively, a memory system controller 115 may operate the write operation independent of a host system 105, and may transmit the data to the local controller 135 or the memory device 130.

In some examples, a stair rhythm or stair rate change may be implemented with more than two steps to further improve performance. For example, the rate change for the data strobe signal 305 may involve three steps, where the controller (e.g., a host system controller 106, a memory system controller 115, a local controller 135) may drive the data strobe signal according to a third rate during a new duration of the write operation that is after the duration 320-b and before the second duration 320-c. In some cases, both the new duration and the duration 320-b may be part of a warm-up period, and the third rate may be greater than the first rate and less than the second rate, so that the rate increases over the durations 320-b through 320-c.

The stair rhythm diagram 302 may illustrate a more granular example of this ramp up process. For example, for a rate corresponding to a periodicity 315-c, any quantity of steps may be included to increase the rate from the start of a warm-up period or duration at 340. For example, for a target rate (e.g., 3600 MT/s) a rate may gradually increase with a different stepped rate (e.g., in a stair configuration as shown in FIG. 3B) for bytes D0 and D1, D2 and D3, D4 and D5, D6 and D7, and D8, where at 345 the rhythm may be at the target rhythm for reading data starting at or after D8. A target rate and stepped rates may be increased for any starting rate or target rate. In some examples, a host system 105 may configure a starting rate, a target rate, a quantity of steps from the starting rate to the target rate, a quantity of bytes per step, an increase in rate per step, corresponding periodicities, among other parameters related to a write operation or other data transfer operation.

In some examples, a rate for the data BUS signal 210 may be flexible, and may not match a rate for the data strobe signal 205. For example, the controller (e.g., a host system controller 106, a memory system controller 115, a local controller 135) may transfer the data using (e.g., in accordance with) the second rate during the duration 320-b and the duration 320-c of the write operation. However, a starting time for transferring the data may be based on, or may be at, an offset value from a start of the first duration. For example, D0-D3 may have a same length as D4, but may start at later time during the duration 320-b instead of at the start of the duration.

The described techniques may be similarly implemented at a memory device 130 for a read operation. For example, in a read operation, a memory device 130 (e.g., via a local controller 135) may receive an RE signal driven by the memory system controller 115 or a host system controller 106. The memory device 130 may recognize the RE signal, and may perform a read operation to read data from one or more memory cells in accordance with, or in response to, the RE signal. The memory device 130 may drive the data strobe signal 305 according to the first rate (e.g., a leisure rate, a leisure rhythm) during a warm-up period including the duration 320-b based on (e.g., matching, in response to) the RE signal being driven at the first rate during a duration (e.g., a third duration) before or at least partially overlapping the duration 320-b. The memory device 130 may also drive the data strobe signal 305 according to the second rate during the duration 320-c in response to the RE signal driven during another previous or overlapping duration (e.g., a fourth duration). In some examples, the controller may be an example of a local controller 135 that may transfer the data to a memory system controller 115, or directly to a host system 105 or a host system controller 106, or may transfer data to the memory system controller 115 which may forward it to a host system 105. Similarly, the rate may include a stair rhythm or may be offset between the data strobe signal 205 and the data BUS signal 210, among all the other features supported and described with respect to a write operation herein.

In some examples, the methods described may improve a performance of a memory system 110 and host system 105 by improving a margin of error and data transfer speed for one or more first bytes of an RE signal or DQs signal. For example, driving an RE signal or DQs signal according to a slower rate during a warm-up period may allow an increase in ONFI speeds due to a relatively low quantity of misreads or miswrites even at higher speeds while using a same strobe drive strength. Operations described herein may also be supported by different interfaces and devices, such as asynchronous interfaces including DDR3 or LPDDR4 interfaces. In some examples, the methods described herein may be utilized for differential signals, as well as for single ended strobe and data BUS signals. Additionally, or alternatively, the methods performed herein may be performed for any procedure or for any strobe signal. Further, while the aspects described herein may be illustrated using a rate for a data strobe signal and a data BUS signal, including DQs signals and DQ BUS signals, such aspects may be utilized during implementation of any other type of strobe or clock signal and data transfer signal for any quantity of channels.

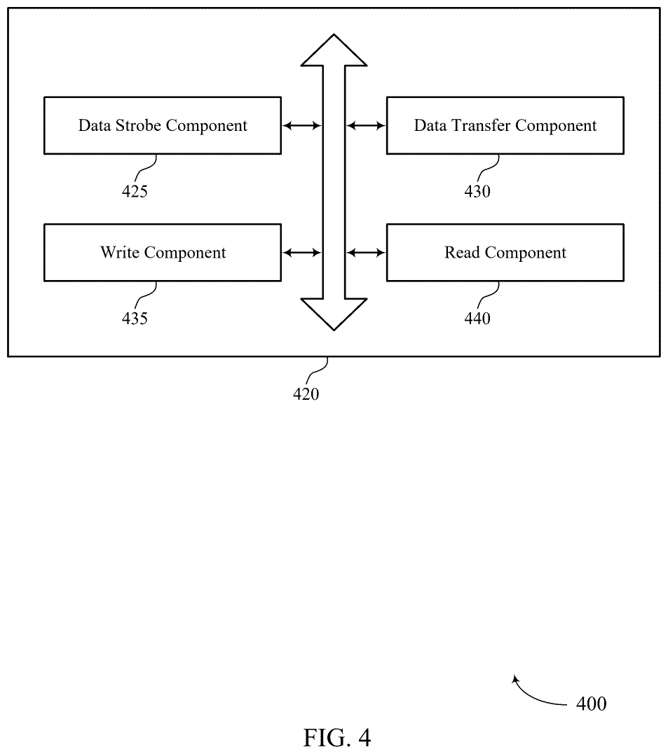

FIG. 4 shows a block diagram 400 of a memory system 420 that supports leisure rhythm for data burst in accordance with examples as disclosed herein. The memory system 420 may be an example of aspects of a memory system as described with reference to FIGS. 1 through 3B. The memory system 420, or various components thereof, may be an example of means for performing various aspects of leisure rhythm for data burst as described herein. For example, the memory system 420 may include a data strobe component 425, a data transfer component 430, a write component 435, a read component 440, or any combination thereof. Each of these components, or components of subcomponents thereof (e.g., one or more processors, one or more memories), may communicate, directly or indirectly, with one another (e.g., via one or more buses).

The memory system 420 may support operating a memory system in accordance with examples as disclosed herein. The data strobe component 425 may be configured as or otherwise support a means for driving a data strobe signal according to a first rate during a first duration of a data transfer operation and according to a second rate during a second duration of the data transfer operation. The data transfer component 430 may be configured as or otherwise support a means for transferring, via a data channel, data of a data burst to a memory device of the memory system during the data transfer operation and based at least in part on driving the data strobe signal according to the first rate during the first duration of the data transfer operation and according to the second rate during the second duration of the data transfer operation.

In some examples, to support transferring data of a data burst, the data transfer component 430 may be configured as or otherwise support a means for transferring the data of the data burst from a memory controller of the memory system to the memory device of the memory system. In some examples, to support transferring data of a data burst, the data transfer component 430 may be configured as or otherwise support a means for receiving the data of the data burst at the memory device from a host system.

In some examples, the write component 435 may be configured as or otherwise support a means for performing a write operation to write the data of the data burst to one or more memory cells of the memory device, where transferring the data of the data burst to one or more memory cells of the memory device is based at least in part on transferring the data of the data burst to the memory device of the memory system.

In some examples, the data strobe component 425 may be configured as or otherwise support a means for driving the data strobe signal according to a third rate during a third duration of the data transfer operation that is after the first duration and before the second duration, where the third rate is greater than the first rate and less than the second rate.

In some examples, transferring the data of the data burst is in accordance with the first rate during the first duration and the second rate during the second duration of the data transfer operation. In some examples, transferring the data of the data burst is in accordance with the second rate during the first duration and the second duration of the data transfer operation. In some examples, a starting time for transferring the data is based at least in part on an offset value from a start of the first duration. In some examples, the first rate is less than the second rate. In some examples, the first duration includes one or more warm-up cycles of a warm-up period for the data transfer operation. In some examples, the data strobe signal includes a single ended signal or a pair of differential signals.

Additionally, or alternatively, the memory system 420 may support operating a memory system in accordance with examples as disclosed herein. In some examples, the data strobe component 425 may be configured as or otherwise support a means for driving a data strobe signal according to a first rate during a first duration of a data transfer operation and according to a second rate during a second duration of the data transfer operation. In some examples, the data transfer component 430 may be configured as or otherwise support a means for transferring, via a data channel, data of a data burst from a memory device of the memory system during the data transfer operation and based at least in part on driving the data strobe signal according to the first rate during the first duration of the data transfer operation and according to the second rate during the second duration of the data transfer operation.

In some examples, to support transferring data of a data burst, the data transfer component 430 may be configured as or otherwise support a means for transferring the data of the data burst from the memory device of the memory system to a memory controller of the memory system. In some examples, to support transferring data of a data burst, the data transfer component 430 may be configured as or otherwise support a means for transferring the data of the data burst from the memory device of the memory system to a host system.

In some examples, the read component 440 may be configured as or otherwise support a means for performing a read operation to read the data of the data burst from one or more memory cells of the memory device, where transferring the data of the data burst from the memory device of the memory system is based at least in part on performing the read operation.

In some examples, the data strobe component 425 may be configured as or otherwise support a means for driving the data strobe signal according to a third rate during a third duration of the data transfer operation that is after the first duration and before the second duration, where the third rate is greater than the first rate and less than the second rate.

In some examples, driving the data strobe signal according to the first rate during the first duration and according to the second rate applicable during the second duration is based at least in part on a read strobe signal (e.g., RE signal) that is driven according to the first rate during a third duration of the data transfer operation and driven according to the second rate during a fourth duration of the data transfer operation.

In some examples, transferring the data of the data burst is in accordance with the first rate during the first duration and the second rate during the second duration of the data transfer operation. In some examples, transferring the data of the data burst is in accordance with the second rate during the first duration and the second duration of the data transfer operation. In some examples, a starting time for transferring the data is based at least in part on an offset value from a start of the first duration. In some examples, the first rate is less than the second rate. In some examples, the first duration includes one or more warm-up cycles of a warm-up period for the data transfer operation. In some examples, the data strobe signal includes a single ended signal or a pair of differential signals.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

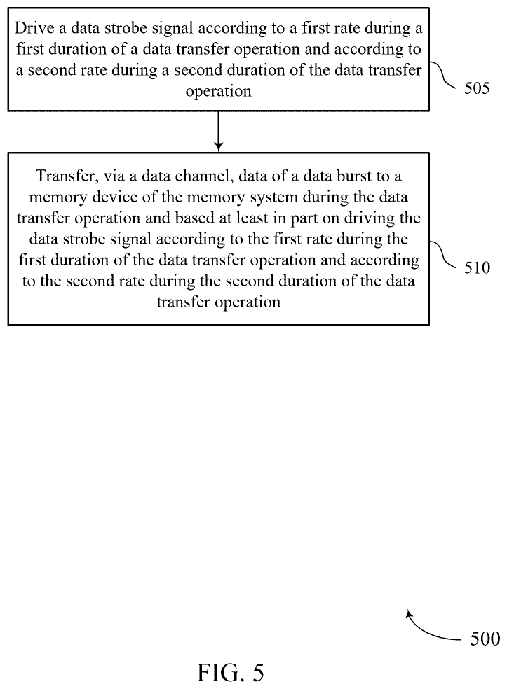

FIG. 5 shows a flowchart illustrating a method 500 that supports leisure rhythm for data burst in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include driving a data strobe signal according to a first rate during a first duration of a data transfer operation and according to a second rate during a second duration of the data transfer operation. In some examples, aspects of the operations of 505 may be performed by a data strobe component 425 as described with reference to FIG. 4.

At 510, the method may include transferring, via a data channel, data of a data burst to a memory device of the memory system during the data transfer operation and based at least in part on driving the data strobe signal according to the first rate during the first duration of the data transfer operation and according to the second rate during the second duration of the data transfer operation. In some examples, aspects of the operations of 510 may be performed by a data transfer component 430 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for driving a data strobe signal according to a first rate during a first duration of a data transfer operation and according to a second rate during a second duration of the data transfer operation and transferring, via a data channel, data of a data burst to a memory device of the memory system during the data transfer operation and based at least in part on driving the data strobe signal according to the first rate during the first duration of the data transfer operation and according to the second rate during the second duration of the data transfer operation.

Aspect 2: The method, apparatus, or non-transitory computer-readable medium of aspect 1, where transferring data of a data burst includes operations, features, circuitry, logic, means, or instructions, or any combination thereof for transferring the data of the data burst from a memory controller of the memory system to the memory device of the memory system and receiving the data of the data burst at the memory device from a host system.

Aspect 3: The method, apparatus, or non-transitory computer-readable medium of any of aspects 1 through 2, further including operations, features, circuitry, logic, means, or instructions, or any combination thereof for performing a write operation to write the data of the data burst to one or more memory cells of the memory device, where transferring the data of the data burst to one or more memory cells of the memory device is based at least in part on transferring the data of the data burst to the memory device of the memory system.

Aspect 4: The method, apparatus, or non-transitory computer-readable medium of any of aspects 1 through 3, further including operations, features, circuitry, logic, means, or instructions, or any combination thereof for driving the data strobe signal according to a third rate during a third duration of the data transfer operation that is after the first duration and before the second duration, where the third rate is greater than the first rate and less than the second rate.

Aspect 5: The method, apparatus, or non-transitory computer-readable medium of any of aspects 1 through 4, where transferring the data of the data burst is in accordance with the first rate during the first duration and the second rate during the second duration of the data transfer operation.

Aspect 6: The method, apparatus, or non-transitory computer-readable medium of any of aspects 1 through 5, where transferring the data of the data burst is in accordance with the second rate during the first duration and the second duration of the data transfer operation and a starting time for transferring the data is based at least in part on an offset value from a start of the first duration.

Aspect 7: The method, apparatus, or non-transitory computer-readable medium of any of aspects 1 through 6, where the first rate is less than the second rate.

Aspect 8: The method, apparatus, or non-transitory computer-readable medium of any of aspects 1 through 7, where the first duration includes one or more warm-up cycles of a warm-up period for the data transfer operation.

Aspect 9: The method, apparatus, or non-transitory computer-readable medium of any of aspects 1 through 8, where the data strobe signal includes a single ended signal or a pair of differential signals.

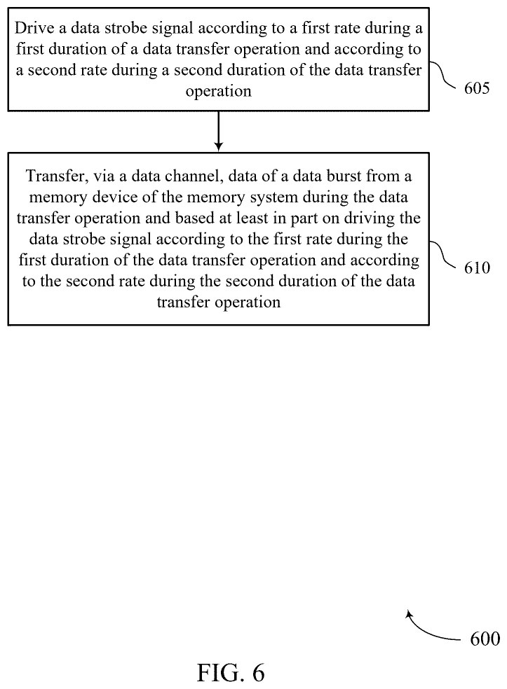

FIG. 6 shows a flowchart illustrating a method 600 that supports leisure rhythm for data burst in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include driving a data strobe signal according to a first rate during a first duration of a data transfer operation and according to a second rate during a second duration of the data transfer operation. In some examples, aspects of the operations of 605 may be performed by a data strobe component 425 as described with reference to FIG. 4.

At 610, the method may include transferring, via a data channel, data of a data burst from a memory device of the memory system during the data transfer operation and based at least in part on driving the data strobe signal according to the first rate during the first duration of the data transfer operation and according to the second rate during the second duration of the data transfer operation. In some examples, aspects of the operations of 610 may be performed by a data transfer component 430 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 10: A method, apparatus, or non-transitory computer-readable medium including operations, features, circuitry, logic, means, or instructions, or any combination thereof for driving a data strobe signal according to a first rate during a first duration of a data transfer operation and according to a second rate during a second duration of the data transfer operation and transferring, via a data channel, data of a data burst from a memory device of the memory system during the data transfer operation and based at least in part on driving the data strobe signal according to the first rate during the first duration of the data transfer operation and according to the second rate during the second duration of the data transfer operation.

Aspect 11: The method, apparatus, or non-transitory computer-readable medium of aspect 10, where transferring data of a data burst includes operations, features, circuitry, logic, means, or instructions, or any combination thereof for transferring the data of the data burst from the memory device of the memory system to a memory controller of the memory system and transferring the data of the data burst from the memory device of the memory system to a host system.

Aspect 12: The method, apparatus, or non-transitory computer-readable medium of any of aspects 10 through 11, further including operations, features, circuitry, logic, means, or instructions, or any combination thereof for performing a read operation to read the data of the data burst from one or more memory cells of the memory device, where transferring the data of the data burst from the memory device of the memory system is based at least in part on performing the read operation.

Aspect 13: The method, apparatus, or non-transitory computer-readable medium of any of aspects 10 through 12, further including operations, features, circuitry, logic, means, or instructions, or any combination thereof for driving the data strobe signal according to a third rate during a third duration of the data transfer operation that is after the first duration and before the second duration, where the third rate is greater than the first rate and less than the second rate.

Aspect 14: The method, apparatus, or non-transitory computer-readable medium of any of aspects 10 through 13, where driving the data strobe signal according to the first rate during the first duration and according to the second rate applicable during the second duration is based at least in part on a read strobe signal that is driven according to the first rate during a third duration of the data transfer operation and driven according to the second rate during a fourth duration of the data transfer operation.

Aspect 15: The method, apparatus, or non-transitory computer-readable medium of any of aspects 10 through 14, where transferring the data of the data burst is in accordance with the first rate during the first duration and the second rate during the second duration of the data transfer operation.

Aspect 16: The method, apparatus, or non-transitory computer-readable medium of any of aspects 10 through 15, where transferring the data of the data burst is in accordance with the second rate during the first duration and the second duration of the data transfer operation and a starting time for transferring the data is based at least in part on an offset value from a start of the first duration.

Aspect 17: The method, apparatus, or non-transitory computer-readable medium of any of aspects 10 through 16, where the first rate is less than the second rate.

Aspect 18: The method, apparatus, or non-transitory computer-readable medium of any of aspects 10 through 17, where the first duration includes one or more warm-up cycles of a warm-up period for the data transfer operation.

Aspect 19: The method, apparatus, or non-transitory computer-readable medium of any of aspects 10 through 18, where the data strobe signal includes a single ended signal or a pair of differential signals.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus for operating a memory system, comprising:
processing circuitry associated with one or more memory devices and configured to cause the apparatus to:
drive a data strobe signal according to a first rate during a first duration of a data transfer operation and according to a second rate during a second duration of the data transfer operation; and
transfer, via a data channel, data of a data burst to a memory device of the memory system during the data transfer operation and based at least in part on driving the data strobe signal according to the first rate during the first duration of the data transfer operation and according to the second rate during the second duration of the data transfer operation.

2. The apparatus of claim 1, wherein, to transfer the data of the data burst, the processing circuitry is configured to cause the apparatus to:
transfer the data of the data burst from a memory controller of the memory system to the memory device of the memory system; or
receive the data of the data burst at the memory device from a host system.

3. The apparatus of claim 1, wherein the processing circuitry is further configured to cause the apparatus to:
perform a write operation to write the data of the data burst to one or more memory cells of the memory device, wherein transferring the data of the data burst to one or more memory cells of the memory device is based at least in part on transferring the data of the data burst to the memory device of the memory system.

4. The apparatus of claim 1, wherein the processing circuitry is further configured to cause the apparatus to:
drive the data strobe signal according to a third rate during a third duration of the data transfer operation that is after the first duration and before the second duration, wherein the third rate is greater than the first rate and less than the second rate.

5. The apparatus of claim 1, wherein transferring the data of the data burst is in accordance with the first rate during the first duration and the second rate during the second duration of the data transfer operation.

6. The apparatus of claim 1, wherein:
transferring the data of the data burst is in accordance with the second rate during the first duration and the second duration of the data transfer operation, and
a starting time for transferring the data is based at least in part on an offset value from a start of the first duration.

7. The apparatus of claim 1, wherein the first rate is less than the second rate.

8. The apparatus of claim 1, wherein the first duration comprises one or more warm-up cycles of a warm-up period for the data transfer operation.

9. The apparatus of claim 1, wherein the data strobe signal comprises a single ended signal or a pair of differential signals.

10. An apparatus for operating a memory system, comprising:
processing circuitry associated with one or more memory devices and configured to cause the apparatus to:
drive a data strobe signal according to a first rate during a first duration of a data transfer operation and according to a second rate during a second duration of the data transfer operation; and
transfer, via a data channel, data of a data burst from a memory device of the memory system during the data transfer operation and based at least in part on driving the data strobe signal according to the first rate during the first duration of the data transfer operation and according to the second rate during the second duration of the data transfer operation.

11. The apparatus of claim 10, wherein, to transfer the data of the data burst, the processing circuitry is configured to cause the apparatus to:
transfer the data of the data burst from the memory device of the memory system to a memory controller of the memory system; or
transfer the data of the data burst from the memory device of the memory system to a host system.

12. The apparatus of claim 10, wherein the processing circuitry is further configured to cause the apparatus to:
perform a read operation to read the data of the data burst from one or more memory cells of the memory device, wherein transferring the data of the data burst from the memory device of the memory system is based at least in part on performing the read operation.

13. The apparatus of claim 10, wherein the processing circuitry is further configured to cause the apparatus to:
drive the data strobe signal according to a third rate during a third duration of the data transfer operation that is after the first duration and before the second duration, wherein the third rate is greater than the first rate and less than the second rate.

14. The apparatus of claim 10, wherein driving the data strobe signal according to the first rate during the first duration and according to the second rate applicable during the second duration is based at least in part on a read strobe signal that is driven according to the first rate during a third duration of the data transfer operation and driven according to the second rate during a fourth duration of the data transfer operation.

15. The apparatus of claim 10, wherein transferring the data of the data burst is in accordance with the first rate during the first duration and the second rate during the second duration of the data transfer operation.

16. The apparatus of claim 10, wherein:
transferring the data of the data burst is in accordance with the second rate during the first duration and the second duration of the data transfer operation, and
a starting time for transferring the data is based at least in part on an offset value from a start of the first duration.

17. The apparatus of claim 10, wherein the first rate is less than the second rate.

18. The apparatus of claim 10, wherein the first duration comprises one or more warm-up cycles of a warm-up period for the data transfer operation.

19. The apparatus of claim 10, wherein the data strobe signal comprises a single ended signal or a pair of differential signals.

20. A non-transitory computer-readable medium storing code comprising instructions which, when executed by one or more processors of a memory system, cause the memory system to:
drive a data strobe signal according to a first rate during a first duration of a data transfer operation and according to a second rate during a second duration of the data transfer operation; and
transfer, via a data channel, data of a data burst to a memory device of the memory system during the data transfer operation and based at least in part on driving the data strobe signal according to the first rate during the first duration of the data transfer operation and according to the second rate during the second duration of the data transfer operation.

21. The non-transitory computer-readable medium of claim 20, wherein the instructions to transfer the data of the data burst, when executed by the one or more processors of the memory system, cause the memory system to:
transfer the data of the data burst from a memory controller of the memory system to the memory device of the memory system; or
receive the data of the data burst at the memory device from a host system.

22. The non-transitory computer-readable medium of claim 20, wherein the instructions, when executed by the one or more processors of the memory system, further cause the memory system to:
perform a write operation to write the data of the data burst to one or more memory cells of the memory device, wherein transferring the data of the data burst to one or more memory cells of the memory device is based at least in part on transferring the data of the data burst to the memory device of the memory system.

23. The non-transitory computer-readable medium of claim 20, wherein the instructions, when executed by the one or more processors of the memory system, further cause the memory system to:
drive the data strobe signal according to a third rate during a third duration of the data transfer operation that is after the first duration and before the second duration, wherein the third rate is greater than the first rate and less than the second rate.

24. The non-transitory computer-readable medium of claim 20, wherein transferring the data of the data burst is in accordance with the first rate during the first duration and the second rate during the second duration of the data transfer operation.

25. The non-transitory computer-readable medium of claim 20, wherein:
transferring the data of the data burst is in accordance with the second rate during the first duration and the second duration of the data transfer operation, and
a starting time for transferring the data is based at least in part on an offset value from a start of the first duration.
